(19) United States
(12) Patent Application Publication
(10) Pub. No.: US 2014/0034829 A1
(43) Pub. Date: Feb. 6, 2014

(54) SYSTEM AND METHOD FOR IRRADIATING AN ETEM-SAMPLE WITH LIGHT

(71) Applicants: Peter Crozier, Tempe, AZ (US); Benjamin Miller, Tempe, AZ (US)

(72) Inventors: Peter Crozier, Tempe, AZ (US); Benjamin Miller, Tempe, AZ (US)

(21) Appl. No.: 13/943,415

(22) Filed: Jul. 16, 2013

Related U.S. Application Data
(60) Provisional application No. 61/680,078, filed on Aug. 6, 2012.

(51) Int. Cl. H01J 37/22

(52) U.S. Cl. CPC H01J 37/226
USPC 250/307; 250/311

(57) ABSTRACT

A system and method for transmission electron microscopy (TEM) of a photocatalyst sample exposed to UV and/or visible light at irradiance levels comparable to those provided by irradiation with sunlight or at least 1,000 W/cm² while maintaining the spatial resolution of interrogation of at least 0.14 nm. Light is delivered to the sample substantially transversely to the sample's surface from an external broadband source through an optical fiber with an output facet formed at an acute angle with respect to the fiber axis. The light delivery system is adapted to not interrupt an operation of auxiliary TEM systems responsible for changing the TEM-chamber environment.

### CROSS-REFERENCE TO RELATED APPLICATIONS

The present application claims benefit of and priority from the U.S. provisional patent application No. 61/680,078 filed on Aug. 6, 2012 and titled “System and method for irradiating an ETEM-sample with light”. The disclosure of the above-identified provisional patent application is incorporated herein by reference in its entirety.

### STATEMENT REGARDING FEDERALLY SPONSORED RESEARCH

This invention was made with government support under DE-SC0004954 awarded by the Department of Energy. The government has certain rights in the invention.

### TECHNICAL FIELD

The present invention relates generally to a system and method for light delivery to a sample subject to examination with a transmission electron microscope (TEM) and, in particular, to a fiber-optic-based system and method of irradiation of such sample with light configured to not interrupt auxiliary functions and capabilities of an environmental TEM that are used during the interrogation of the sample with the TEM.

### BACKGROUND

Photocatalysis is a field of energy research that currently attracts a lot of attention and requires to quantitatively connect structure and processing of catalyst material with their properties and performance, both of which should preferably be enhanced. Often the structural features involved in catalytic processes are at the nano-scale or below. Currently available techniques used for characterization of the catalyst materials, including the characterization with a transmission electron microscopy, would benefit from being enhanced. For example, enhancing current environmental TEM studies of a photocatalyst sample (such as titania or TiO₂, for example) by providing high intensity visible and UV illumination of the sample within an environmental transmission electron microscope (ETEM) may allow the user to analyze, in real time, the interaction between light and a photocatalyst under reaction conditions.

### SUMMARY

Embodiments of the invention provide a transmission-electron microscope (TEM) system for interrogation of a photocatalyst sample. Such TEM system includes a TEM chamber containing an electron gun and an electron lens such that the electron gun and electron lens define a first direction of propagation of an electron beam. The TEM system further includes a holder configured to support the photocatalyst sample a surface of which is positioned substantially perpendicularly to the first direction; and a fiber-optic component having an axis extended in a second direction that is substantially transverse to the first direction. The fiber-optic component is configured to deliver irradiating light from outside of the TEM chamber towards the photocatalyst sample and irradiate the photocatalyst sample with a beam of so delivered irradiating light at an angle of about 70 degrees or less as measured between an axis of said beam of light and a normal to the surface of the photocatalyst sample. In one embodiment, the fiber-optic component includes a multimode quartz optical fiber defining an output facet of the fiber-optic component at an acute angle with respect to the axis. In a specific embodiment, the acute angle is about 60 degrees. The TEM system may further include a light source adapted to generate the irradiating light characterized by a broad-band optical spectrum and disposed externally with respect to the TEM chamber, and at least one of a reflective optical component positioned to focus the irradiating light on an input facet of the fiber optic component and an optical filter disposed such as to transmit the irradiating light therethrough. In a specific embodiment, the TEM system optionally further includes an auxiliary device operably associated with the holder and configured to facilitate one or more of introduction of gas to the surface of the photocatalyst sample and changing a temperature of the photocatalyst sample during an interrogation of the photocatalyst sample with the electron beam. Here, the fiber-optic component is disposed such that an operation of the auxiliary device remains uninterrupted during such interrogation.

Embodiments of the invention further provide a method for interrogation of a photocatalyst sample with a transmission electron microscope (TEM) system. The TEM system includes a TEM chamber containing a sample holder, an electron gun and an electron lens. The TEM system additionally includes at least one auxiliary device operably associated with the holder and adapted to predeterminably achieve at least one of a reactive gas environment around the sample and variation of a temperature of the sample. The electron gun and electron lens define a first direction corresponding to propagation of an electron beam. The method of interrogation includes (i) positioning the photocatalyst sample in the TEM chamber, with a surface of the sample being substantially perpendicular to the electron beam; (ii) transmitting the electron beam through the photocatalyst sample to form an image associated with the sample on a TEM screen; and (iii) irradiating a surface of the photocatalyst sample with light delivered from outside of the TEM chamber through a fiber-optic component that has an axis extending in a second direction. The second direction is generally substantially transverse to the first direction. The irradiance of the irradiating light on the incident surface of the sample is at least 1,000 mW/cm². In addition, the method may include activating such auxiliary device such to establish interaction between the reactive gas and the surface of the photocatalyst sample and/or change the temperature the photocatalyst sample such that the process of irradiation of the surface of the sample with light delivered through the fiber-optic component does not impede either of the process of interaction and changing the temperature. In a specific implementation, the process of irradiation of the sample includes illuminating the surface of the photocatalyst sample with delivered light at an angle of about 70 degrees or less (as measured between an axis of said beam of light and a normal to the surface of the photocatalyst sample) through an output facet of the fiber-optic component, where the output facet is formed at an acute angle with respect to the optical axis of the fiber-optic component

### BRIEF DESCRIPTION OF THE DRAWINGS

The invention will be more fully understood by referring to the following Detailed Description in conjunction with the Drawings, of which:

FIGS. 1A and 1B are schematic diagrams of a conventional transmission electron microscope.

FIG. 2 is a diagram illustrating the spatial coordination of the sample holder, the electron column, and the port in a wall of the chamber in a Tecnai F20 TEM.

FIGS. 3A and 3B are diagrams illustrating modifications to a TEM system according to an embodiment of the invention, configured to allow an optical fiber to enter the chamber substantially perpendicularly to the sample rod and to have no physical contact with the holder.

FIG. 4 is a partial cut-out view of a fiberoptic holder/manipulator for use with an embodiment of the invention. The fiber tip is positioned using this apparatus. The brass guide tube is supported by three support rods which are attached to the vacuum feedthrough. The feedthrough is positioned using micrometers, and the movement is facilitated by a bellows.

FIG. 5 is a diagram illustrating schematically an optical train for light delivery from a light source to the fiber-optic component according to an embodiment of the invention.

FIG. 6 shows plots illustrating spectral distributions of irradiances of sunlight and light delivered to and incident onto a photocatalyst sample according to the embodiment of the invention. Additionally shown is a plot demonstrating spectral bands achieved by activating an optical filter of the optical train of FIG. 5.

FIGS. 7A and 7B demonstrate an embodiment of a fiber-optic component for use with a system and method of the invention.

FIG. 8 is a contour plot showing the calculated irradiance achieved by delivery of irradiating light from the external source of FIG. 5 to the central portion (of about 1.6 mm in diameter) of the photocatalyst sample.

FIG. 9 shows several plots demonstrating irradiance distribution of light emanating from the output facet of the fiber-optic component of FIGS. 7A, 7B. The intensity distributions found for 3 horizontal planes at a series of distances from the fiber tip, showing the spreading of the beam as distance increases. In the TEM, the actual distance is approximately 2 mm. These distributions were obtained using an optical microscope, and each is a composite of 5-7 images at a range of exposure times. The inset shows a filled contour plot of the 2 mm distance with contours at every 5% of the maximum intensity. The inset also includes a dashed circle indicating the size of a 3 mm TEM grid, in comparison to the distribution.

FIG. 10 is a plot showing the results of an in-situ optical measurement of the irradiance as a function of position inside the TEM system. The lower axis gives the distance from the location of maximum intensity along all three Cartesian directions (in reference to the manipulator of FIG. 4) which can be precisely varied using the translation stage of the microscope. The upper axis shows the rotation around the sample holder axis. All measurement series are normalized relative to their maximum value.

FIG. 11 shows two images of the same particle of anatase TiO₂. The left image was taken with the light off, while the right image is taken with the light on, as well as with 67 Pa (about 0.5 torr of water vapor and heated to 150° C. The diffractograms of both images, shown above the imaged, exhibit faint lattice fringes at about 2.5 nm, corresponding to the (002) planes, thereby demonstrating that the lattice can still be observed while heating and illuminating the sample in a gaseous environment.

FIG. 12 shows diffractograms generated by Digital Micrograph from images of two different gold particles. The diffractogram on the left shows information being transferred up to 0.144 nm when the light delivered to the sample is off, while the diffractogram on the right shows a similar information limit while the light is turned on.

### DETAILED DESCRIPTION

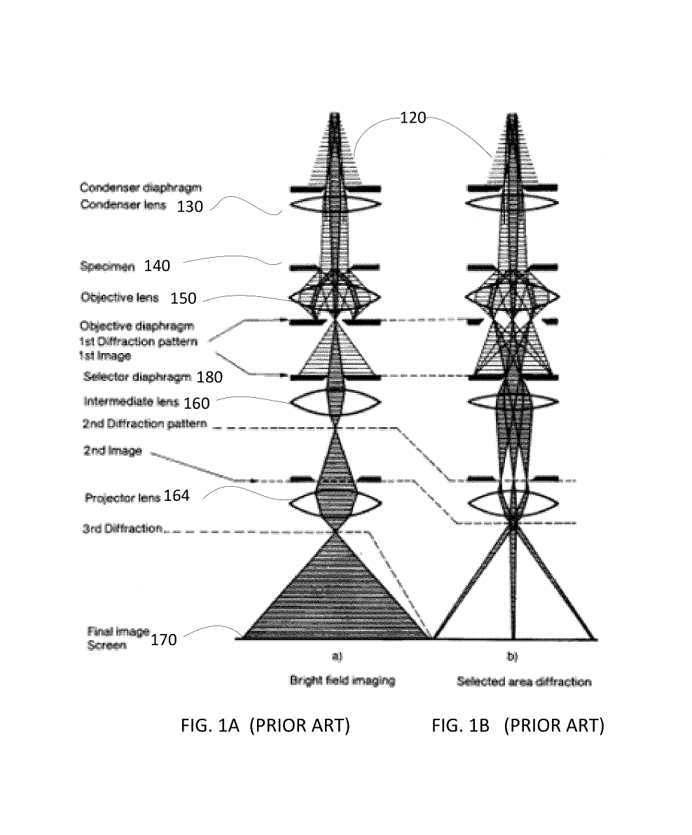

The transmission electron microscope (or TEM) is an optical analogue to the conventional light microscope. Its operation is based on the fact that electrons can be ascribed a wavelength (of the order of about 2.5 pm) and interact with magnetic fields as a point charge. In operation, a beam of electrons is applied instead of a beam of light, and glass lenses are replaced by magnetic lenses. The lateral resolution of the best TEMs is comparable with atomic resolution. A schematic presentation of the microscope is shown in FIGS. 1A and 1B. The bright field imaging mode of operation of the TEM is shown schematically in FIG. 1A, while the diffraction mode of operation is illustrated in FIG. 1B. With an electron gun (not shown) an electron beam 120 is formed, which is later accelerated by an electric field formed due to a voltage difference of, typically, 200 kV. The electron beam is focused with condenser lens 130 to a spot with dimensions on the order of 1 mm or so on sample under test (SUT) or specimen 140 that is positioned substantially perpendicularly to the direction of propagation of the electron beam 120. The first image, which is formed by the objective lens 150, may be magnified (in one example, about 25 times). The following intermediate lens 160 provides additional magnification of the image (usually with a magnification coefficient of more than 10⁶). Additionally and optionally, to form images of thin samples, an electron diffraction pattern can also be formed with a projector lens 164 on the final image screen 170. In bright field imaging, the image of a thin sample 140 is formed by the electrons that pass the sample substantially without diffraction, and the diffracted electrons being stopped by a selector diaphragm 180. In comparison, in a diffraction mode, diffracted beam(s) are used for imaging. Typically, the microstructure of the SUT 140 is studied in an imaging mode (such as, for example, a bright field imaging mode corresponding to FIG. 1A), while the crystalline structure is studied in the diffraction mode. The chemical composition of small volumes (such as, for example, grain boundaries), can be obtained by detection of x-rays emitted from the SUT.

In-situ TEM encompasses a broad range of techniques which attempt to couple various stimuli of the TEM sample with high resolution imaging. One stimulus which is of interest currently is irradiation of sample with light. In a specific case, when the SUT is a photocatalyst, such irradiation provides a near-reaction conditions and the results of the study may facilitate design of efficient photocatalysts based on understanding of a link between the catalyst microstructure and interaction with light. Optical irradiation of other materials for other characterization purposes may also be carried out (for example, to assess luminescence properties of as a function of local position or composition of a structure). An environmental TEM (ETEM) can be used to study catalysts in situ under conditions of high temperature or in a reactive gas environment. However, the light irradiation experienced by a photocatalyst during use is rarely reproduced in situ, leaving absent a critical experimental condition for studying light-induced processes. According to an embodiment of the invention, an ETEM is adapted for observing the structure, of a photocatalyst sample irradiated with UV and/or visible light, at a scale relevant to catalytic activity. A material absorbing visible and/or UV light is changed slightly by such absorption. For example, chemical reactions can be driven which change the structure or composition of a material, electrons may be promoted to the conduction band in semiconductors, or excited in metals, and these events may become observable. One of the applications of such study is formation of novel nanostructured material for solar energy conversion.

According to the idea of the invention, a system of delivery of light from an external broad-band source to the SUT within the TEM chamber is adapted such that operation of auxiliary element(s) and sub-system(s) of the TEM system that change the environment around the SUT remain operational even when the SUT is irradiated with light. Light-delivery systems of related art possess a shortcoming in that the presence of such light-delivery systems in the TEM chamber impedes the operation of the auxiliary sub-systems (such as sub-systems providing cooling or heating of the sample, or sub-systems adapted to introduce a reactive gas into the chamber). Light has to be delivered to a surface of the SUT at a substantially small angle (as measured with respect to the normal to the surface of the SUT). The presence of optical system(s) inside the TEM chamber has been reported to interfere with the operation of the auxiliary system, for example by blocking their operation during a period of light delivery. (In such a case, simultaneous light delivery and, for example, introduction of the reactive gas in the chamber becomes problematic.)

References throughout this specification to “one embodiment,” “an embodiment,” “a related embodiment,” or similar language mean that a particular feature, structure, or characteristic described in connection with the referred to “embodiment” is included in at least one embodiment of the present invention. Thus, appearances of the phrases “in one embodiment,” “in an embodiment,” and similar language throughout this specification may, but do not necessarily, all refer to the same embodiment. It is to be understood that no portion of disclosure, taken on its own and/or in reference to a figure, is intended to provide a complete description of all features of the invention.

In addition, in drawings, with reference to which the following disclosure may describe features of the invention, like numbers represent the same or similar elements wherever possible. In the drawings, the depicted structural elements are generally not to scale, and certain components are enlarged relative to the other components for purposes of emphasis and understanding. It is to be understood that no single drawing is intended to support a complete description of all features of the invention. In other words, a given drawing is generally descriptive of only some, and not all, features of the invention. A given drawing and an associated portion of the disclosure containing a description referencing such drawing do not, generally, contain all elements of a particular view or all features that can be presented is this view in order to simplify the given drawing and the discussion, and to direct the discussion to particular elements that are featured in this drawing.

A skilled artisan will recognize that the invention may possibly be practiced without one or more of the specific features, elements, components, structures, details, or characteristics, or with the use of other methods, components, materials, and so forth. Therefore, although a particular detail of an embodiment of the invention may not be necessarily shown in each and every drawing describing such embodiment, the presence of this detail in the drawing may be implied unless the context of the description requires otherwise. In other instances, well known structures, details, materials, or operations may be not shown in a given drawing or described in detail to avoid obscuring aspects of an embodiment of the invention that are being discussed. Furthermore, the described features, structures, or characteristics of the invention may be combined in any suitable manner in one or more embodiments.

Moreover, if the schematic flow chart diagram is included, it is generally set forth as a logical flow-chart diagram. As such, the depicted order and labeled steps of the logical flow are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow-chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Without loss of generality, the order in which processing steps or particular methods occur may or may not strictly adhere to the order of the corresponding steps shown.

The invention as recited in the appended claims is intended to be assessed in light of the disclosure as a whole.

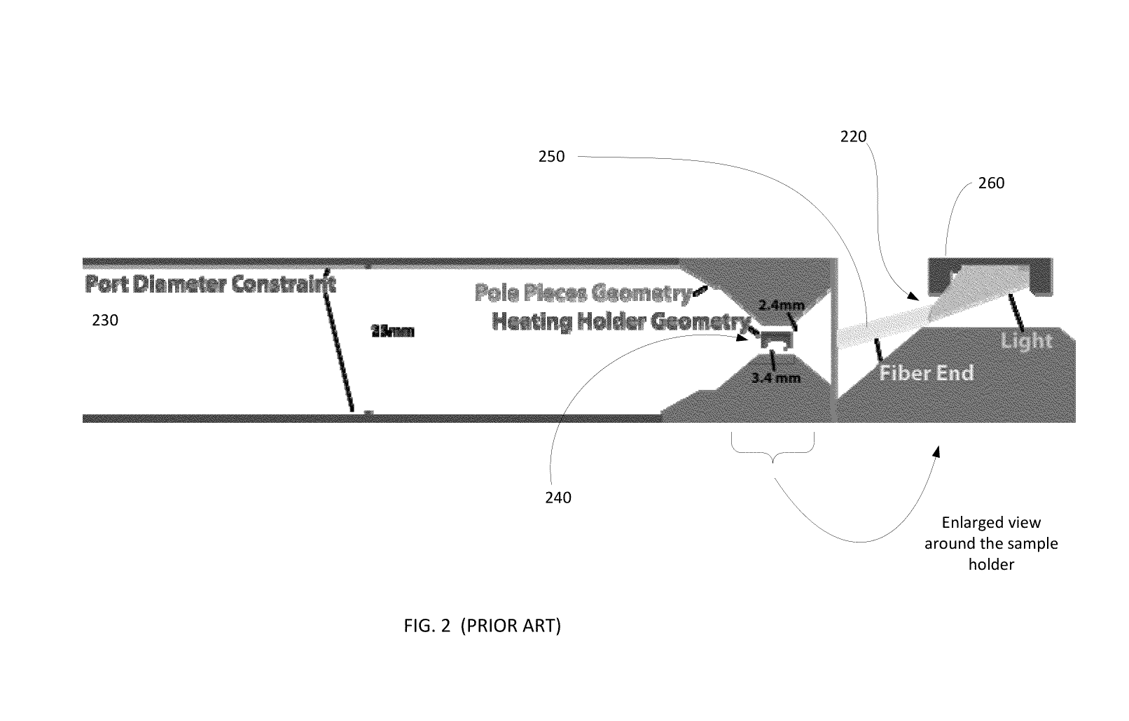

The guiding of light to the sample area of the TEM with the use of an optical fiber can be arranged by threading the optical fiber along the sample rod, or by introducing the fiber into the chamber through a port on the side of the column. Using a specially designed sample rod is rather problematic, especially if the user of the microscope wants to simultaneously use other commercially available holders to introduce another capability to the microscope, such as heating, cooling, or electrical/mechanical measurements/stimuli. In reference to a diagram of FIG. 2, placing a fiber output tip 220 in a required proximity to the sample, after going through a port 230 on the column is also non-trivial, because space 240 available in the TEM column is limited (especially in the pole piece gap), and an optical fiber 250 may not be bent to a radius smaller than a certain threshold value without introducing significant optical losses. Because the critical bend radius for a typical multimode optical fiber is substantially larger than the radius of the port on the microscope through which bent fiber must pass, the maximum angle at which the fiber can approach the surface of the sample is rather large (as measured with respect to the surface normal). These limitations are schematically shown in a diagram of FIG. 2.

Additional geometrical and/or space limitations may be introduced by the use of an individual holder. In further reference to FIG. 2, the Gatan heating holders 260 (often used in the Tecnai F20 ETEM) are approximately 2.4 mm thick, with an inner diameter of about 3.4 mm. Care must be taken to position the output end of the fiber such that the walls of the furnace in the heating holder do not cast a shadow onto the sample area. Finally, it is essential for the overall flexibility of the system, that the fiber tip 220 be far enough from the sample, that the holder may be freely tilted (and, more generally, repositioned) without contacting the fiber 250 (while certain tilts may result in reduction of light irradiance at the sample).

One consideration defining the configuration of a system of light delivery to the sample is the spatial distribution of light at the sample. Once such distribution is characterized outside of the TEM chamber and the amount of light coupled into the fiber is known, the irradiance of light striking the sample in a region of interest defined by position of the electron beam at the sample can be determined. It is desirable for the light delivered to the sample to be confined to a substantially to a small spot on the sample so that high intensities (generally, over 1,000 mW/cm²) are achieved, even at moderate beam power levels. Accordingly the use of a high brightness source of light is necessitated. The high intensities produced in this way are useful for studying materials under a variety of illumination conditions, and allow for studies of solar energy materials under conditions similar to concentrated sunlight schemes.

Defining the spectral distribution of the source of light is also essential. For some solar applications, for example, it may be advantageous to utilize a broadband light source having a spectrum that closely resembles the spectrum of the sun. For other applications, and for many fundamental experiments, it is useful to use a narrow range of incident wavelengths/energies in order to isolate the effect of photons of a particular energy (for example, above or below the bandgap of a semiconductor sample) on such semiconductor sample. The available spectrum should preferably range from the UV (for example, from about 200 nm) up through the entire visible spectrum. Optionally, optical filters can be used to define the spectrum of light delivered to the sample from the spectrum of light produced by the source of light. In some applications, a light source may include a laser or a semiconductor laser (optionally, a wavelength tunable laser). In other applications, the light source may include a superluminescent light emitting diode. Generally, a light source of choice should meet certain criteria impose by the intended application such as, for example, have specific value of brightness or be amenable to be represented, in approximation, as a point source.

Additional considerations dictate that an embodiment of the invention be configured to ensure that the output tip and/or facet of the fiber in the proximity of the sample is repositionable and/or spatially realignable, and that the spatial resolution of characterization of the photocatalyst sample with the electron beam remain no less than about 0.14 nm. Such performance should be satisfied with or without presence of a reactive gas in the TEM chamber (up to a few torr of pressure) and with or without heating of the sample up to about 500° C., while the level of irradiance of light (delivered to the surface of the sample at an angle of at least 45 degrees with respect to the direction of propagation of the electron beam or, alternatively, with respect to the normal to the sample's surface) at least of about 2 to 3 mWcm⁻² nm⁻¹ in the visible range and at least 1 mWcm⁻² nm⁻¹ in the UV range. These values exceed the AM 1.5 solar spectral irradiance that peaks at about 0.14 mWcm⁻² nm⁻¹ in the visible range.

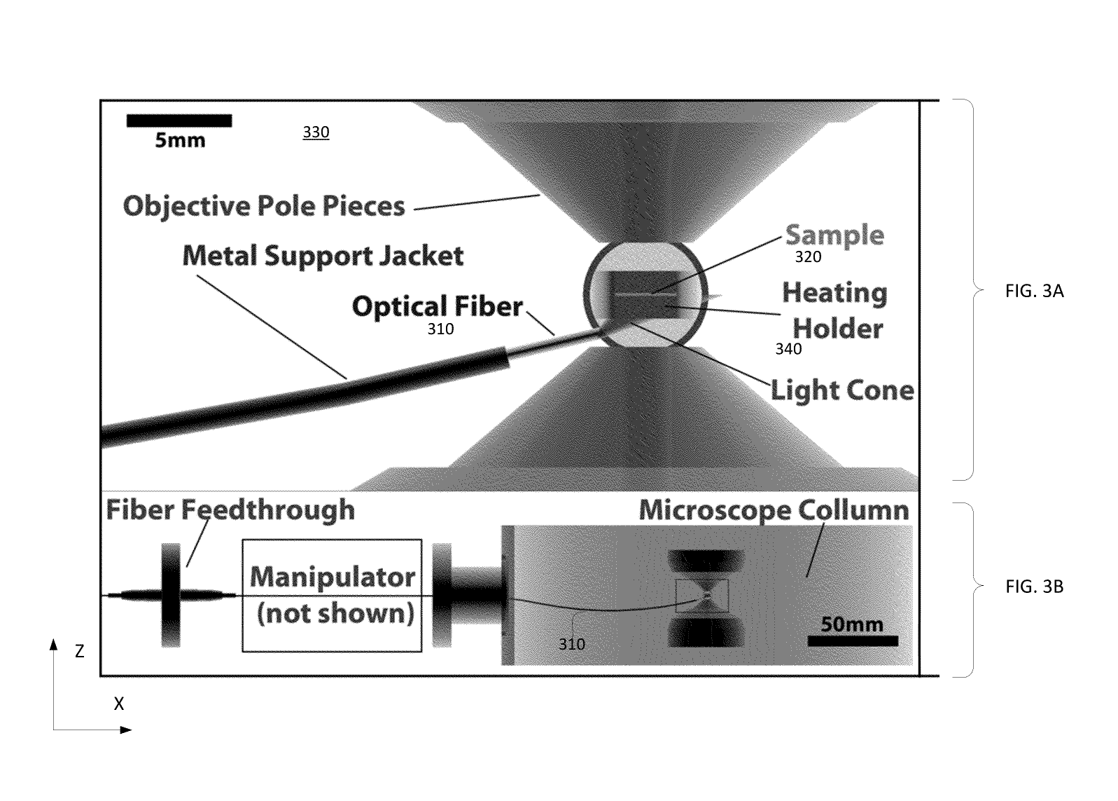

According to an embodiment of the invention, illustrated in FIGS. 3A and 3B, a multimode optical fiber 310 is used to guide light produced by a high-brightness broadband source (not shown, such as, for example, an LDLS EQ-99, a laser driven xenon plasma source developed by Energetiq, that is located outside of the TEM chamber) to a point just below the photocatalyst sample 320 positioned in the chamber 330 of the FEI Tecnai F20 environmental TEM. As shown, the fiber 310 enters the ETEM in a direction substantially perpendicular to that defined by the sample rod, and has no physical contact with the sample holder 340. Generally, the fiber 300 extends in a plane that is substantially transverse to a direction of propagation of the electron beam defined by an electron gun and an electron lens of the TEM (not shown). Such configuration permits movement, tilting, heating and cooling of the sample with little impact on the optical fiber.

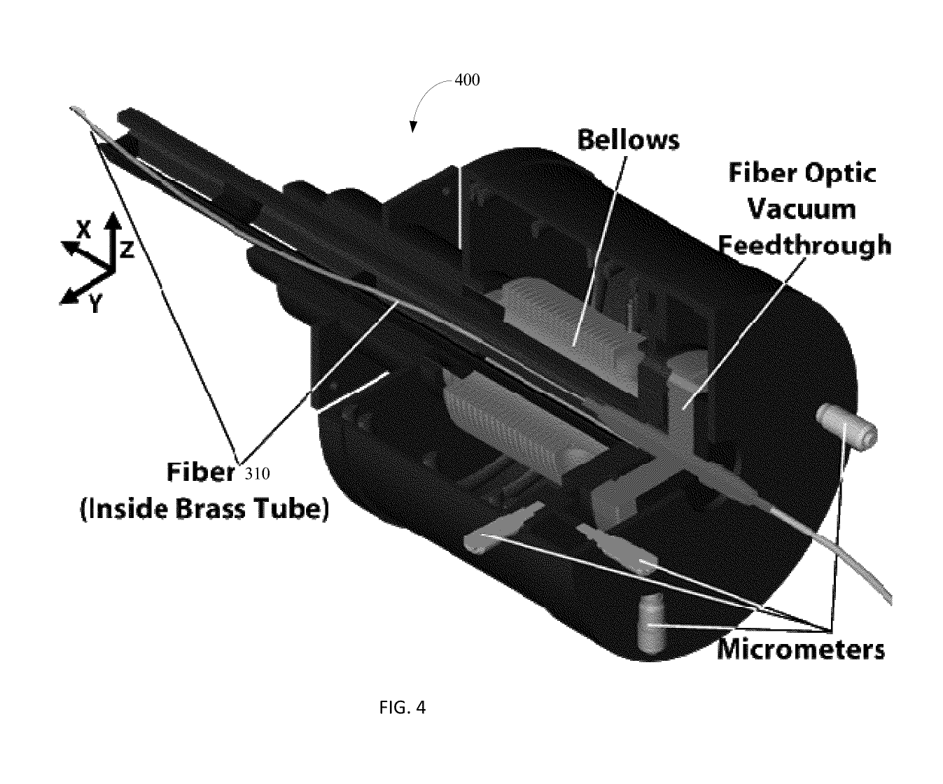

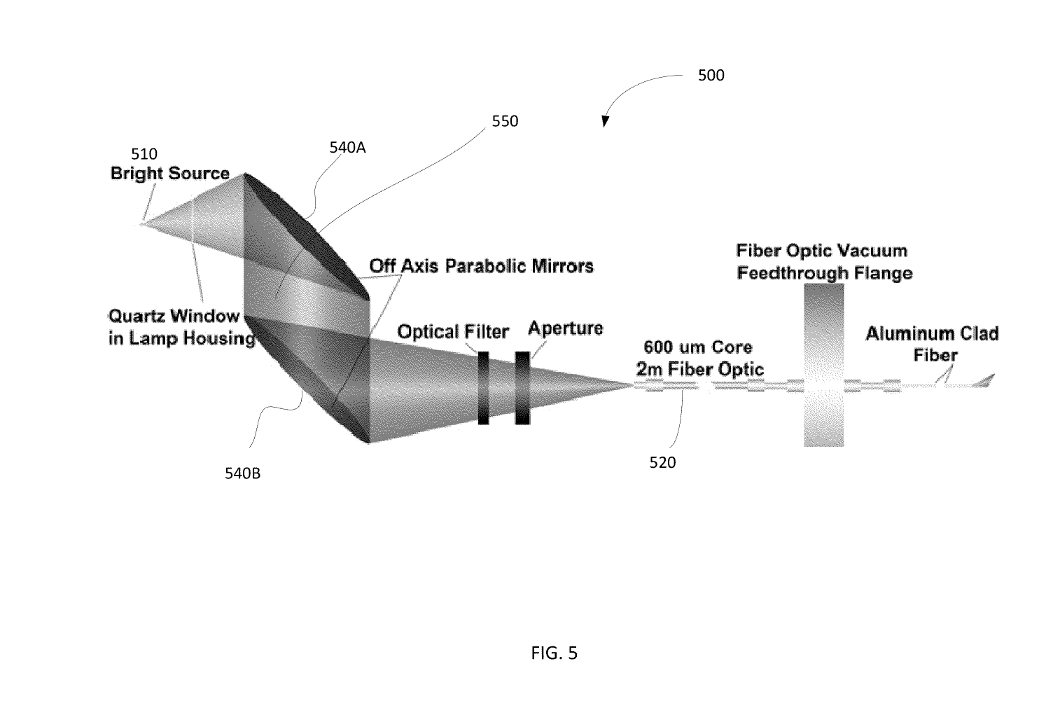

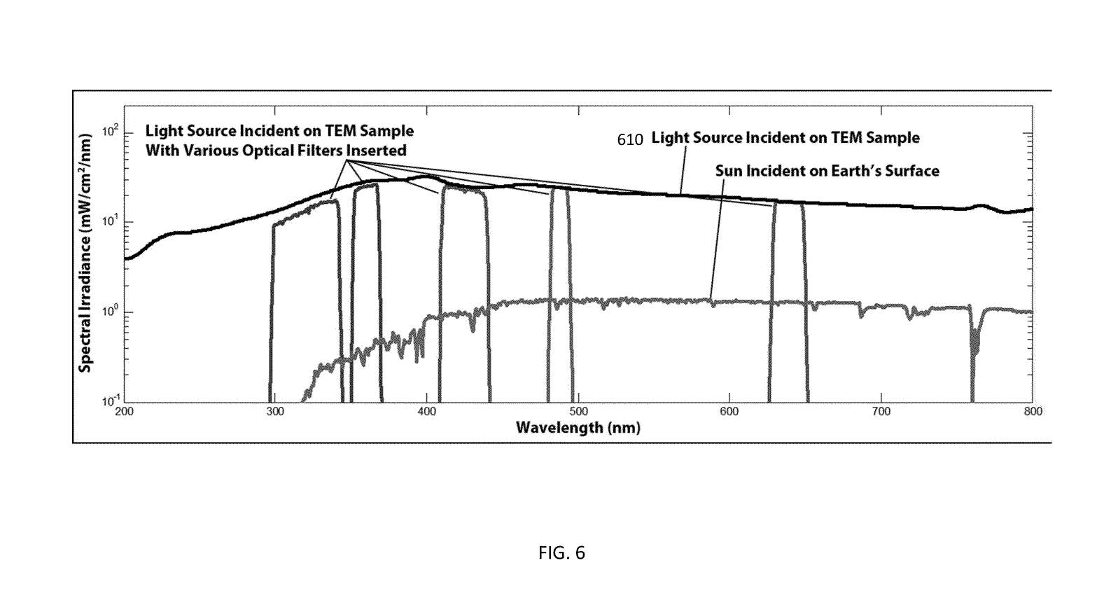

In reference to FIGS. 3B and 4, the alignment of the fiber 310 with respect to the sample and the electron beam is facilitate with an XYZ micro-manipulator and holder 400 supporting the fiber 310. The schematic of an optical train 500 used for coupling of light from the external broad-band source of light 510 into the fiber 520 is shown in FIG. 5. Here, the diameter of the source of light 510 is approximately 100 μm. This allows the light generated by the source 510 to be focused onto an approximately 600 μm core fiber 520 with minimal loss. Since the coupled light then exits farther down the optical train from the approximately 600 μm fiber (in the vicinity of the TEM sample, not shown in FIG. 5), the light spot can be quite small, and thus the resulting irradiance correspondingly high. Focusing light 530 emitted from the source 510 onto the input facet of the fiber 520 is accomplished with the use of two off-axis parabolic mirrors 540A, 540B. In the embodiment of FIG. 5 no lenses are used, as these would introduce undesirable chromatic aberrations. The first mirror 540A substantially collimates the light into a beam 550, which is propagated towards the second mirror 540B and is further that focused onto the input facet of the fiber 520. Optionally, additional optical components such as, for example, at least one optical filter 560 and an iris diaphragm 570 are removably and irreplaceably positioned across the beam of light between the source 510 and the fiber 520. Examples of the spectra of light 510, exemplary optical filter(s) 560, and various other optical components of the system, and a selection of filters has been calculated from the various manufacturers' spectra and is shown in FIG. 6.

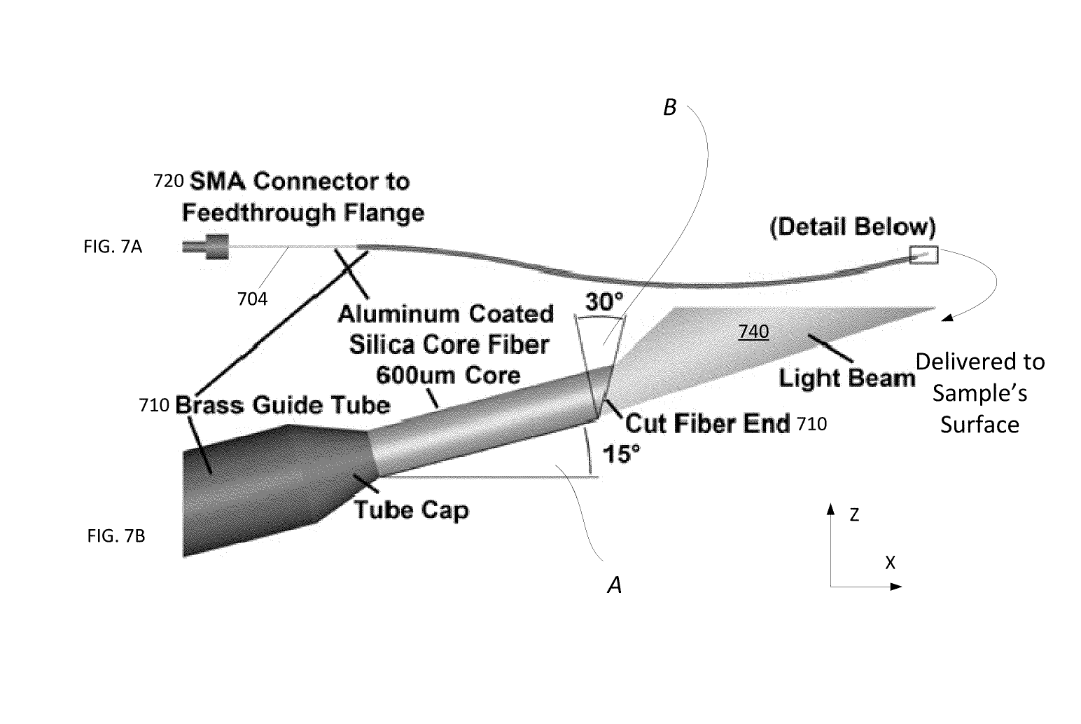

In one embodiment, two optical fibers are employed. One is a 2 m long, 600 micrometers in diameter silica core silica clad high OH solarization resistant fiber assembly (from Ocean Optics) that runs from the focal point of the second mirror to the fiber feed through flange which allows light to pass into the fiber on the high vacuum of the microscope. In reference to FIGS. 7A and 7B, and referring again to FIG. 3A, the second fiber inside the TEM was specially ordered from Ocean Optics; it also has a 600 μm core diameter, with silica cladding and additionally protected by an aluminum buffer (rather than the standard polymer based protective buffer and jacket). This aluminum buffer fulfills many of the design criteria for the fiber, making it additionally electrically-conductive. As a result, the fiber tip does not charge up, nor does the fiber outgas and/or degrade in vacuum or reactive gas atmosphere of the TEM chamber. The aluminum buffer is non-magnetic, and can be heated to relatively high temperatures. Optionally, to deliver the UV light to the sample from the external source 510 of FIG. 5, the quartz-based optical fibers are used. Other optical fibers may also be used, provided that, in operation, the charging of the fiber tip and/or outgassing of the fiber material is minimized.

An optical fiber used for light delivery according to an embodiment of the invention has a critical bend radius. When bent at a radius smaller than the critical bend radius, such fiber starts leaking light thereby increasing optical losses. Because of this restriction, as well as the limited space in the microscope chamber, the angle that the output facet (cut substantially perpendicularly to the axis of the fiber) can form with respect to the surface of the sample to be irradiated is limited to a maximum angle A in the xz-plane (as shown, at about 15 degrees with respect to the surface of the sample). The curve along which the optical fiber 704 is bent inside the TEM chamber, as shown in FIG. 7A, substantially confirms to the 25 cm critical bend radius (as defined by the parameters of the fiber used in the embodiment of FIGS. 7A, 7B), while bringing the fiber to this maximum angle. To maintain the fiber's contour along the path of FIG. 7A, a brass tube 710 (non-magnetic and conducting) is used, which is flared on one end for easy insertion of the fiber, and has a cap on the other end to securely position the fiber tip. In further reference to FIG. 4, the tube is itself held in place by three aluminum support rods, which are connected to the fiber feed through.

One end of the optical fiber 704 is terminated by a standard SMA connector 720, which connects to the high vacuum side of the feed through flange; the fiber output end 730 near the sample is cut at about 60 degree angle with respect to the fiber axes (shown, indirectly, via an angle B defined with respect to a normal to the fiber axis) to form an output facet correspondingly inclined. This cut provides additional advantages in that it facilitates the delivery of output (irradiating) light 740 c to the sample center at an angle that is maximized with respect to the direction of the electron beam (or to the direction defined by a normal to the sample's surface). As a result, the delivered light 740 is not blocked by the walls of the heating holder used in the TEM chamber.

In further reference to FIG. 4, the fiber is precisely positioned relative to the microscope through the use of a manipulation stage. The movement of the fiber is facilitated by a bellows, which is appropriately connected to the microscope. This movement is controlled by micrometers in each of the three Cartesian directions with about 3 mm of travel. Optionally, an positioning element operable to retract the fiber and supporting structures away from the center of the microscope by a predetermined distance (for example, about 1.5 cm), is additionally built in (not shown). Such capability minimizes the danger of striking the pole pieces with the fiber or supporting rods when the apparatus is attached or detached from the TEM column. It also allows the entire apparatus to remain attached to the microscope, while keeping the fiber tip far from the sample area when TEM users are not utilizing the light source in their experiments. Finally, lead shielding is appropriately located in the design to ensure safety from x-rays generated by the high energy electron beam in the TEM. In one implementation, and in further reference to FIG. 6, the system of the invention is operable to irradiate the sample at the region of interest defined by the intersection of the electron beam with the surface of the sample with spectral irradiance of at least 2 mW/cm²/nm within the spectral range from about 200 nm to about 800 nm (which, is about 10 times that generated by the Sun on the surface of the Earth).

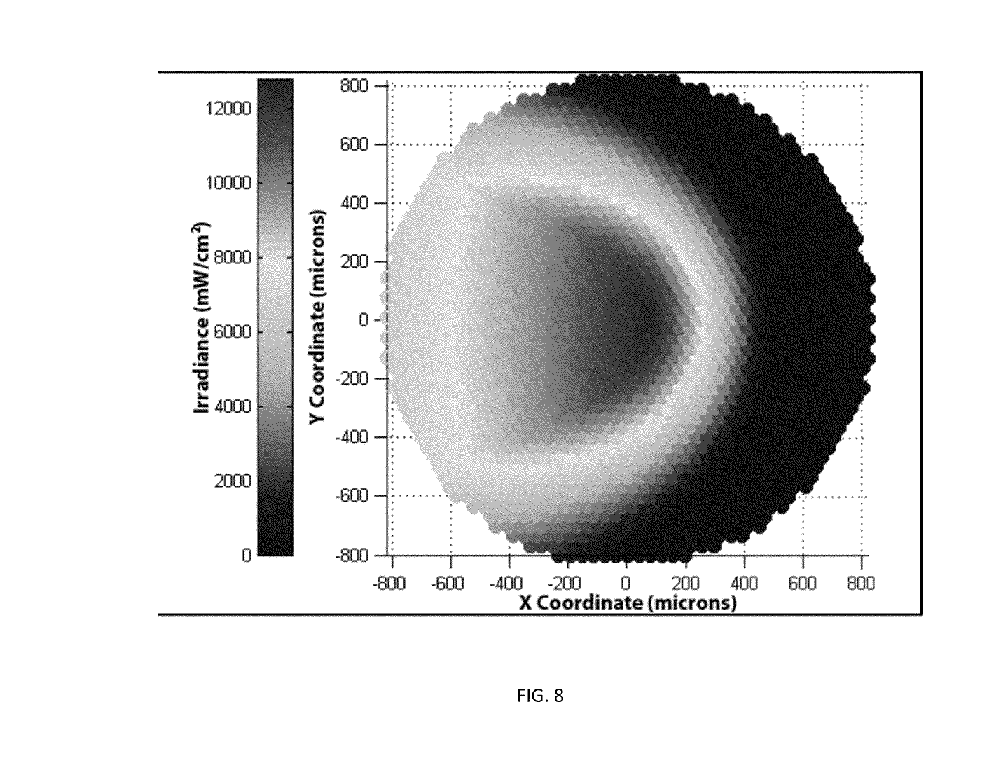

FIG. 8 shows the results of a theoretical calculation of the irradiance as a function of position across the photocatalyst sample. The hot stage used for the environmental studies occludes some of the TEM sample, so only the relevant section of the sample is shown. For this assessment, the fiber end is treated as a large number of point sources, each emitting uniformly into a cone characteristic of the fiber end geometry, and it is assumed that light of irradiance the value of which does not depend on wavelength is directed onto the sample. (A reasonable approximation to this ideal can be achieved through the use of a high brightness, broadband light source coupled with filters, as shown in FIG. 6.)

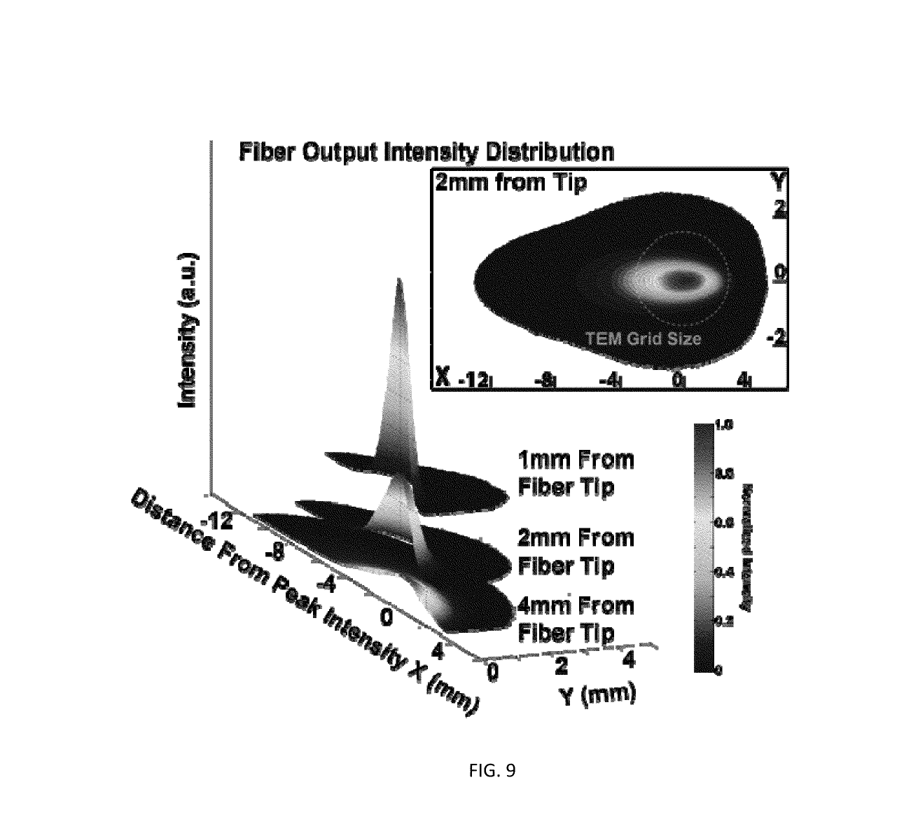

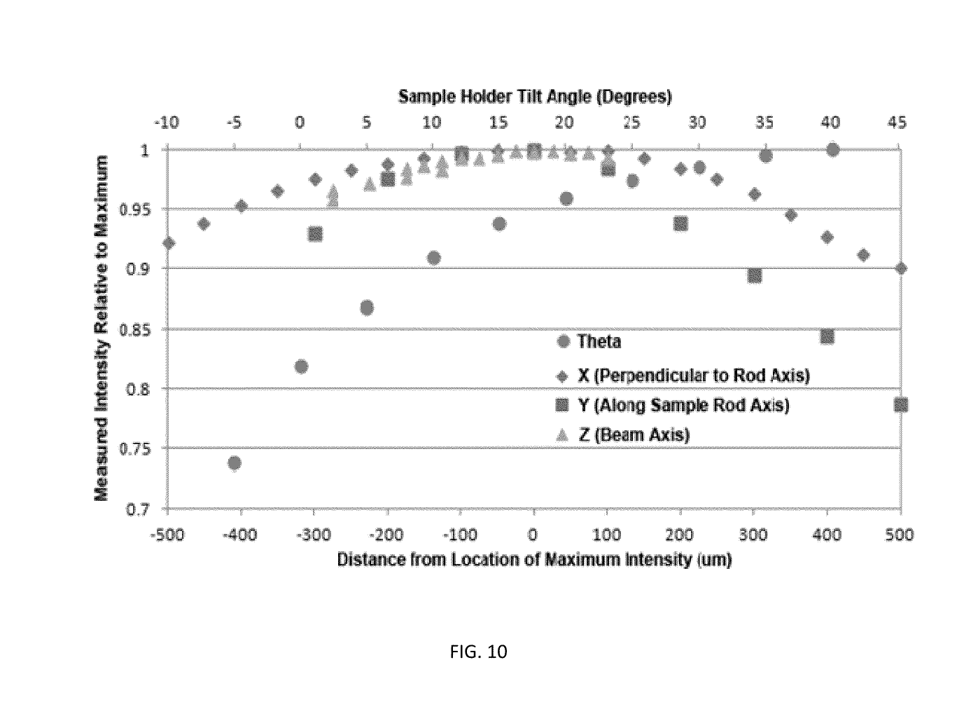

The operation of the embodiment of FIGS. 3A, 3B, 7A, 7B was characterized both in situ and ex situ. Outside the ETEM, an optical microscope was used to characterize the irradiance distribution of the output 740 of FIG. 7B. The fiber manipulator was set up to illuminate a small translucent screen which was observed using a Lumenera Infinity-2 microscope. The screen was moved with respect to the fiber, to characterize the distribution at a series of distances from the fiber tip 710. Multiple exposures were taken at every position at the screen, and, using the known exposure times, the corresponding images were merged, using a computer processor, to form a single distribution of light across the screen. FIG. 9 illustrates 3 of such distributions for a series of distances from the fiber tip 710 to the screen. The distribution most relevant for the TEM is shown in the inset. In the y direction, the full-width-half-maximum (FWHM) of the irradiance distribution is about 1.06 mm, and the peak is substantially Gaussian; in the x direction, the FWHM is about 2.45 mm, and the peak shape demonstrates an asymmetric profile. The maximum detected irradiance is about 1,456 mW/cm². Precise alignment of the delivered light 740 on the photocatalyst sample in the holder of the TEM (such as, for example, the holder 340 of FIG. 3A) is essential. Immediately after the fiber manipulator was mounted onto the TEM column, a process which requires the column vacuum to be broken, and the initial alignment may be observed directly by removing the objective aperture blade and viewing the fiber tip 710 through the objective aperture port. After this rough alignment was completed, a specially constructed photodiode detector was inserted into the TEM via the specimen airlock. This small photodiode was built into a TEM sample holder rod and could be precisely positioned at the sample position between the upper and lower objective lens pole pieces. This allowed for a direct determination of the location and irradiance of the light beam. The size of the photodiode was about 1 mm², while the light distribution on the sample was about 1 mm wide by 2 mm long so that at any given detector position, a large area of the light distribution was sampled. Measurements of the distribution obtained using optical microscopy given in FIG. 9 as a contour plot yielded a condition for alignment of the fiber with respect to the optic axis of the microscope. To maintain an intensity level at the optic axis of at least 90% of the maximum, the distribution should preferably be within about 0.4 mm of center in the x-direction, and within about 0.2 mm of center in the y-direction. The in-situ technique utilizes this photodiode sample holder designed for aiding alignment. The results of this technique are shown in FIG. 10. From this figure it is clear that the intensity falling on the detector has a well defined maximum when it is translated along the x, y and z directions. The maximum is significantly broader than the maximum seen in the distribution characterized ex-situ, because the detector area is large, thus smoothing the measured intensity distribution. From the angular dependence, it can be seen that the measured intensity increases as the photodiode is tilted around the sample rod axis so that it more closely aligns to face the light beam direction. Correlating these precise distributions, with the in situ measurements inside the microscope, it is possible to calculate the intensity that is incident on the TEM sample, with good accuracy, and reasonable spatial resolution. This is essential for interpreting results obtained using this illumination technique. The intensity that was achieved on the TEM sample on the optic axis was about 1,460 mW/cm². Scaling the distribution obtained using the optical microscope to this maximum intensity value, it was possible to integrate the distribution to obtain the total power in the beam emitted by the fiber inside the microscope. The total power is about 45.63 mW (which is about 6% of the nominal power emitted by the external light source 510 of the embodiment, show in FIG. 5). Irradiance of visible light delivered to the photocatalyst sample 320 of FIG. 3A is about an order of magnitude higher than that of the AM 1.5 solar spectrum.

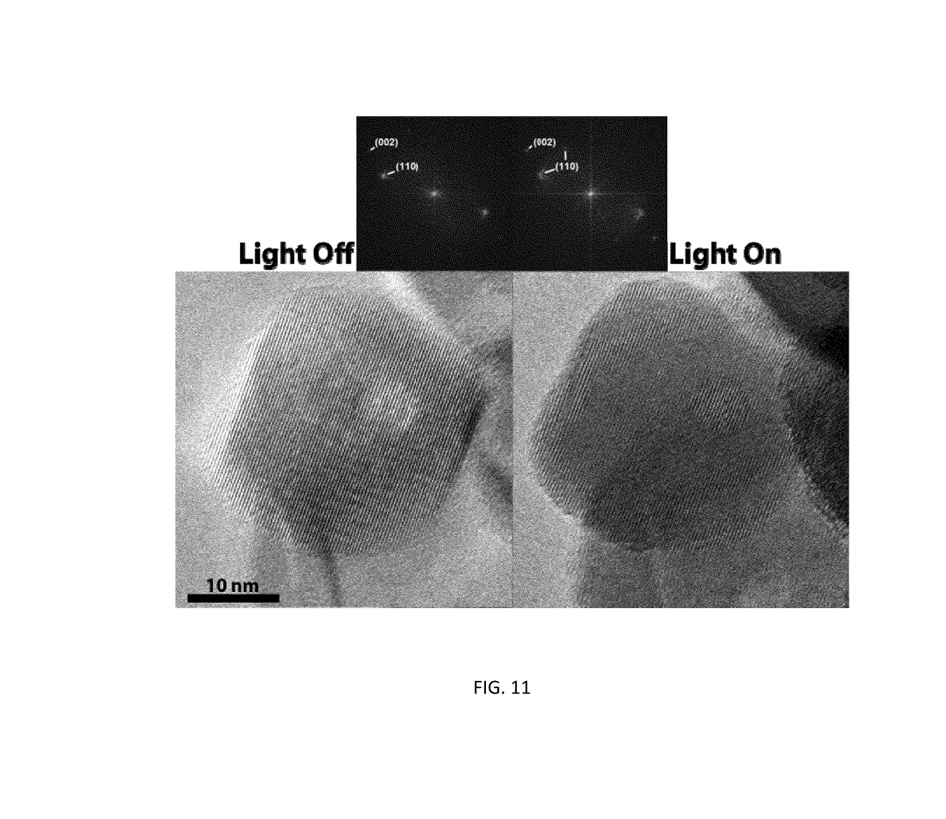

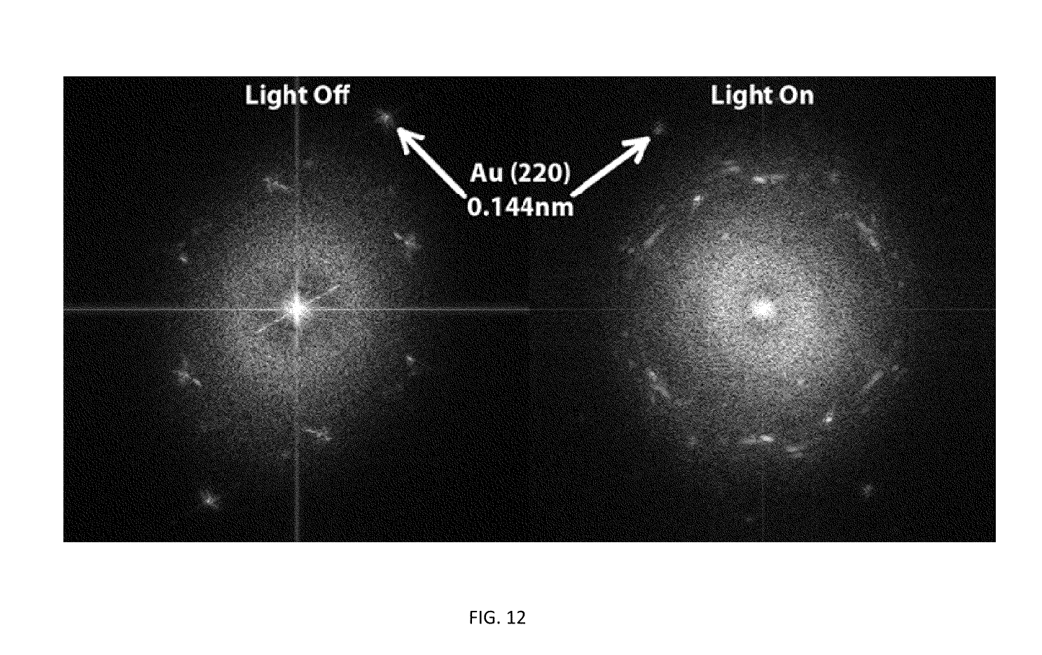

Evaluation of the performance of the TEM microscope itself during the process of irradiation of the sample 320 with light, according to an embodiment of the invention, showed that the performance of the TEM was not degraded noticeably by the addition of the fiber illumination system. FIG. 11 provides imaged of a particle of TiO₂ taken by the embodiment of a TEM system of the invention over the course of several days in the presence of water vapor and at 150° C. At the beginning of the experiment, the light source 510 of FIG. 1 was turned off, resulting in the image on the left of FIG. 11. The right image shows the same particle being illuminated by the light 740 delivered from the external source 510 in accordance with the invention. In both images, lattice fringes of about 2.5 nm can be seen with the use of the FFT. In a more demanding test, illustrated with FIG. 12, the information limit of the TEM system is shown to be substantially unchanged by the addition of the operating light source 510 and the delivery of light 740 for irradiation of the sample 320. Both diffractograms of FIG. 12 are calculated from images that were taken while the fiber 704 of FIGS. 7A, 7B in its working position, and clearly show Au {220} lattice fringes out to about 0.144 nm, near the quoted value of the information limit of the Tecnai F20 (which is about 0.14 nm). This calculation demonstrates that the TEM system's resolution is not degraded by electrostatic charging of the fiber tip, or by magnetic interference from the fiber or guide rods. The image on the right is also taken with the light source 510 turned on (and, therefore, with light 740 incident onto the sample 320), thereby indicating that any vibrations or EM interference produced by the operating light source 510 are also not degrading microscope performance.

Illuminating the TEM sample is essential for studying nanostructured photocatalysts at the smallest length scales in an environment similar to the one they will experience in actual use. Many factors must be considered when designing a system for performing such illumination. The design just described successfully balances these various considerations, and has been shown to not have a significantly detrimental effect on the performance of the microscope, while illuminating the sample with over about 1 W/cm² of broadband UV and visible light. The opportunity now exists to perform many novel in-situ experiments utilizing light illumination, temperature control, and reactive gas atmospheres, which may provide interesting results for nanostructured photocatalyst materials.

At least some of embodiments of the invention may include the use of a processor controlled by instructions stored in a tangible, non-transitory memory. The memory may be random access memory (RAM), read-only memory (ROM), flash memory, a device readable by a computer I/O attachment, such as CD-ROM or DVD disks, for example), information alterably stored on writable storage media (e.g. floppy disks, removable flash memory and hard drives) or information conveyed to a computer through communication media, including wired or wireless computer networks. In addition, while the invention may be embodied in software, the functions necessary to implement the invention may optionally or alternatively be embodied in part or in whole using firmware and/or hardware components, such as combinatorial logic, Application Specific Integrated Circuits (ASICs), Field-Programmable Gate Arrays (FPGAs) or other hardware or some combination of hardware, software and/or firmware components.

Modifications to, and variations of, the illustrated embodiments may be made without departing from the inventive concepts disclosed herein. Furthermore, disclosed aspects, or portions of these aspects, may be combined in ways not listed above. Accordingly, the invention should not be viewed as being limited to the disclosed embodiment(s).

What is claimed is:

1. A transmission-electron microscope (TEM) system for interrogation of a photocatalyst sample, the TEM system comprising:
a TEM chamber;
an electron gun and an electron lens in the TEM chamber, said electron gun and an electron lens defining a TEM column and a first direction of propagation of an electron beam;
a holder configured to support the photocatalyst sample with a surface thereof positioned substantially perpendicularly to said first direction; and
a fiber-optic component having an axis extended in a second direction that is substantially transverse to said first direction, said fiber-optic component configured to deliver irradiating light from outside of the TEM chamber towards the photocatalyst sample and irradiate said photocatalyst sample with a beam of so delivered irradiating light at an angle of about 70 degrees or less as measured between an axis of said beam of light and a normal to the surface of the photocatalyst sample.

2. A TEM system according to claim 1, wherein said fiber-optic component includes a multimode quartz optical fiber defining an output facet of said fiber at an acute angle with respect to said axis.

3. A TEM system according to claim 2, wherein the acute angle is about 60 degrees.

4. A TEM system according to claim 1, further comprising a light source adapted to generate said irradiating light characterized by a broad-band optical spectrum and disposed externally with respect to the TEM chamber, and at least one of a reflective optical component positioned to focus the irradiating light on an input facet of the fiber optic component and an optical filter disposed to transmit said irradiating light.

5. A TEM system according to claim 1, further comprising an auxiliary device operably associated with the holder and configured to facilitate one or more of introduction of gas to the surface of the photocatalyst sample and changing a temperature of the photocatalyst sample during an interrogation of said sample with the electron beam, and wherein said fiber-optic component is disposed such that an operation of said auxiliary device remains uninterrupted during said interrogation.

6. A method for interrogation of a photocatalyst sample with a transmission electron microscope (TEM) system having a TEM chamber containing said sample in a holder, an electron gun and an electron lens therein, and further containing at least one auxiliary device operably associated with the holder and adapted to predeterminably achieve at least one of a reactive gas environment around said sample and variation of a temperature of said sample, said electron gun and electron lens defining a first direction corresponding to propagation of an electron beam, the method comprising:
positioning the photocatalyst sample, in said TEM chamber, with a surface thereof being substantially perpendicular to the electron beam;
transmitting the electron beam through the photocatalyst sample to form an image thereof on a TEM screen; and
irradiating a surface of the photocatalyst sample, with light delivered from outside of the TEM chamber through a fiber-optic component having an axis extending in a second direction substantially transverse to the first direction, with an irradiance level of at least 1,000 mW/cm².

7. A method according to claim 6, further comprising activating the at least one auxiliary device such as to establish interaction of the reactive gas and the surface of the photocatalyst sample or change of the temperature of said photocatalyst sample, and wherein said irradiation a surface does not impede either said interaction of said reactive gas and said surface or said change of the temperature.

8. A method according to claim 6, wherein said irradiating includes illuminating said surface of the photocatalyst sample with said delivered light at an angle of about 70 degrees or less, as measured between an axis of said beam of light and a normal to the surface of the photocatalyst sample, through an output facet of the fiber-optic component, said output facet formed at an acute angle with respect to said axis.
